(19) United States
(12) Patent Application Publication
(10) Pub. No.: US 2026/0269512 A1
(43) Pub. Date: Sep. 10, 2026

(54) CONNECTOR

(71) Applicant: YAZAKI CORPORATION, Tokyo (JP)

(72) Inventors: Tatsuya Shiraishi, Kakegawa-shi (JP); Yasuhiro Yamaguchi, Kakegawa-shi (JP)

(21) Appl. No.: 19/536,112

(22) Filed: Feb. 10, 2026

(30) Foreign Application Priority Data
Mar. 5, 2025 (JP) 2025-034540

(51) Int. Cl. H01R 13/502; B60L 53/16; H01R 13/506; H01R 13/514; H01R 13/52

(52) U.S. Cl. CPC H01R 13/502; B60L 53/16; H01R 13/506; H01R 13/514; H01R 13/5202; H01R 13/5213

(57) ABSTRACT

A connector includes: a terminal member; a connector housing configured to hold the terminal member; a refrigerant accommodating body configured to be accommodated in the connector housing in a state of being in contact with the terminal member; and a refrigerant configured to circulate in the refrigerant accommodating body from outside.

### CROSS-REFERENCE TO RELATED APPLICATION(S)

This application is based upon and claims the benefit of priority from prior Japanese patent application No. 2025-034540 filed on Mar. 5, 2025, the entire contents of which are incorporated herein by reference.

### BACKGROUND

### 1. Field of the Invention

The present disclosure relates to a connector.

### 2. Description of the Related Art

A connector (charging inlet) provided in a vehicle such as an electric automatic vehicle or a plug-in hybrid automatic vehicle has been used in the related art to supply (charge) electric power from outside of the vehicle to a battery mounted in the vehicle. In such a connector, a large current is required in order to increase a capacity of a mounted power storage device, shorten a charging time, and the like. However, when the current is increased, temperature rise of the connector increases due to heat generated at a terminal connection portion of the connector by energization. Therefore, in a connector having a terminal connection portion such as a charging inlet, a connector capable of restraining temperature rise during energization has been proposed (for example, see JP2020-113448A, JP2020-187920A, JP2021-19499A, JP2022-25813A and JP2022-7469A).

A connector disclosed in JP2020-113448A includes a vehicle-side terminal (terminal member), a connector housing that holds the vehicle-side terminal, and a heat storage body accommodated in the connector housing. The heat storage body includes a case accommodated in the connector housing and a heat storage material accommodated in the case. Therefore, the heat storage material of the heat storage body absorbs heat generated at the terminal, and thus sudden temperature rise of the terminal or the like can be restrained.

A connector disclosed in JP2020-187920A includes a terminal (terminal member) and a heat storage body. The terminal includes a holding portion formed integrally with a terminal connection portion and an electric wire connection portion. The heat storage body is held by the holding portion. The heat storage body includes a heat storage material (latent heat storage material) accommodated in the inside (sealed space) of a case held by the holding portion. The heat storage material can absorb heat generated at the terminal. Therefore, sudden temperature rise of the terminal can be restrained.

In a liquid-cooled charging system for a vehicle disclosed in JP2021-19499A, a fluid circuit extends along components (a contact terminal, a housing, and the like) of a charging assembly. Therefore, a refrigerant flows through the fluid circuit, and heat can be dissipated from the components of the charging assembly during charging of the vehicle.

A cooling device for a charging inlet for a vehicle disclosed in JP2022-25813A includes a power receiving terminal (terminal member), a housing that holds the power receiving terminal, and a charging inlet cooling circuit which is connected to a battery cooling circuit and to which a refrigerant is supplied. A flow path for the refrigerant supplied from the charging inlet cooling circuit is formed in the housing. Therefore, during charging, the refrigerant flows through the flow path in the housing that holds the power receiving terminal, and the power receiving terminal held by the housing can be cooled.

A connector disclosed in JP2022-7469A includes, inside a terminal (terminal member), a refrigerant flow path through which a refrigerant flows. Therefore, during charging, the refrigerant flows through the refrigerant flow path in the terminal, and the terminal can be cooled.

However, in the connector disclosed in JP2020-113448A and JP2020-187920A, since the heat storage material stores heat, temperature rise of a heat generating portion becomes gentle and the temperature can be restrained, but when a large current flows, a temperature requirement cannot be satisfied only by heat storage.

In the cooling method disclosed in JP2022-25813A, the sudden temperature rise during energization can be restrained by circulating the refrigerant in the flow path, but since the heat of the terminal is cooled via the housing, a thermal resistance is large, and it is difficult to satisfy a higher temperature requirement.

In the connector disclosed in JP2021-19499A and JP2022-7469A, the refrigerant flow path through which the refrigerant flows is formed in the terminal, and an electric wire conductor of a cable and a cooling tube must be connected to the terminal, which complicates a structure of the terminal. Therefore, a problem exists that a manufacturing cost of the connector increases.

### SUMMARY

The present disclosure has been made in view of the above circumstances, and an object thereof is to provide a connector that can restrain temperature rise of a terminal member during energization and is easily manufactured.

In order to achieve the above object, a connector according to the present disclosure is characterized as follows.

According to an aspect of the present disclosure, there is provided a connector including: a terminal member; a connector housing configured to hold the terminal member; a refrigerant accommodating body configured to be accommodated in the connector housing in a state of being in contact with the terminal member; and a refrigerant configured to circulate in the refrigerant accommodating body from outside.

According to the present disclosure, it is possible to provide a connector that can restrain temperature rise of a terminal member during energization and is easily manufactured.

The present disclosure has been briefly described above. Further, the details of the present disclosure can be clarified by reading modes (hereinafter, referred to as "embodiments") for carrying out the invention described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is an overall perspective view of a connector according to a first embodiment of the present disclosure;

FIG. 2 is a sectional view taken along a line II-II in FIG. 1;

FIG. 3 is an exploded perspective view of the connector illustrated in FIG. 1;

FIG. 4 is a perspective view of a refrigerant accommodating body illustrated in FIG. 3;

FIG. 5 is a partially cutaway perspective view of the refrigerant accommodating body illustrated in FIG. 4 as viewed from the rear;

FIG. 6 is a partially cutaway perspective view illustrating a state in which the refrigerant accommodating body is fixed to a terminal member;

FIG. 7 is a perspective view of a connector housing in which the refrigerant accommodating body is accommodated, as viewed a rear side;

FIG. 8 is a sectional view taken along a line VIII-VIII in FIG. 1;

FIG. 9 is an exploded perspective view of a refrigerant accommodating body according to a modification;

FIG. 10 is a longitudinal sectional view of a connector according to a second embodiment of the present disclosure;

FIG. 11 is a perspective view illustrating a state in which a refrigerant accommodating body illustrated in FIG. 10 is fixed to the terminal member, as viewed from the rear;

FIG. 12 is a longitudinal sectional view of a connector according to a reference example; and

FIG. 13 is a perspective view illustrating a state in which a heat storage member illustrated in FIG. 12 is fixed to the terminal member.

### DETAILED DESCRIPTION OF THE INVENTION

Specific embodiments according to the present disclosure will be described below with reference to the drawings.

### First Embodiment

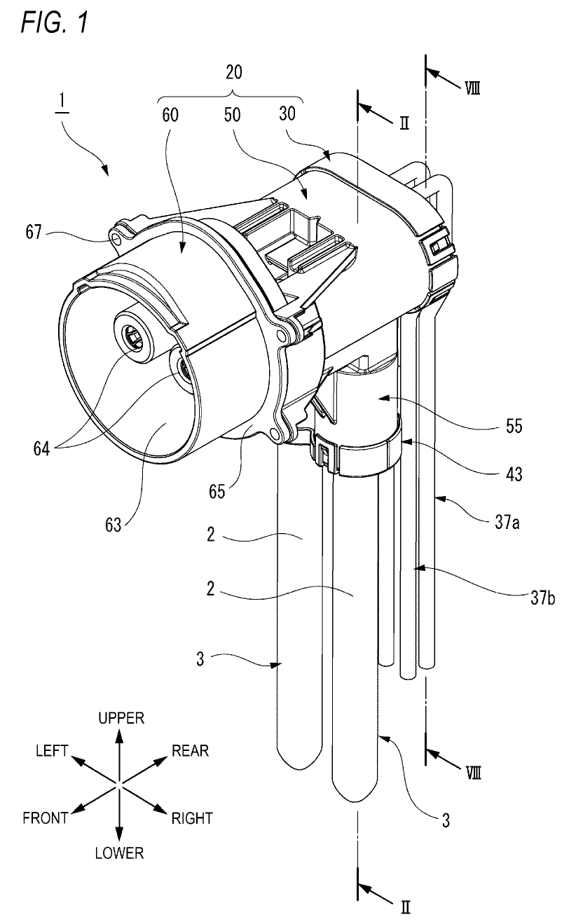

A charging inlet 1, which is a connector according to a first embodiment of the present disclosure, is provided in a vehicle such as a plug-in hybrid automatic vehicle or an electric automatic vehicle, and is connected to an electric wire extending from a battery mounted in the vehicle. By fitting a counterpart connector (so-called charging gun) into a recessed fitting portion 63 (see FIG. 1 and the like) of the charging inlet 1, electric power is supplied to the battery from outside of the vehicle, and the battery is charged.

Hereinafter, for convenience of description, as illustrated in FIG. 1, a "front-rear direction", a "left-right direction", and an "upper-lower direction" are defined. The "front-rear direction", the "left-right direction", and the "upper-lower direction" are orthogonal to one another. The front-rear direction corresponds to a fitting direction of the charging inlet 1 and the counterpart connector (not illustrated). A front side in the fitting direction (a side closer to the counterpart connector) as viewed from the charging inlet 1 is referred to as a "front side", and a release side in the fitting direction (a side away from the counterpart connector) as viewed from the charging inlet 1 is referred to as a "rear side".

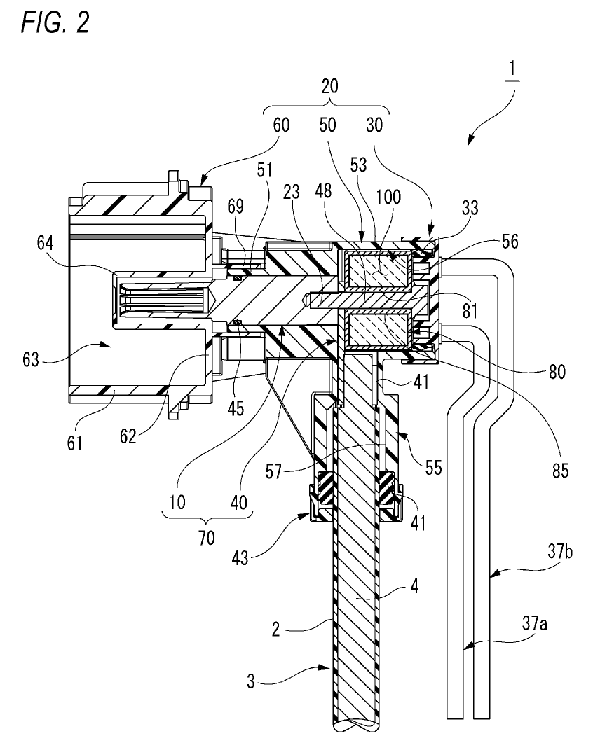

As illustrated in FIGS. 1 to 3, the charging inlet 1 according to the first embodiment includes a pair of terminal members 70 to each of which one end portion of corresponding one of a pair of electric wires 3 is electrically connected, a pair of refrigerant accommodating bodies 80 that are respectively fixed in contact with the terminal members 70, and a connector housing 20 that accommodates the pair of terminal members 70 and the pair of refrigerant accommodating bodies 80. The other end portion of each of the pair of electric wires 3 is connected to a battery (not illustrated). Each of the electric wires 3 includes a core wire 4 and a sheath 2 made of an insulating resin and covering the core wire 4 (see FIG. 2). Hereinafter, components constituting the charging inlet 1 will be described in order.

First, the connector housing 20 will be described.

In this example, as illustrated in FIGS. 1, 2, and the like, the connector housing 20 includes a holder 50, a housing body 60, and a cover 30. The holder 50 and the housing body 60 are framework components of the connector housing 20, and constitute a part of an outer surface of the connector housing 20. Of course, the connector housing according to the present disclosure is not limited thereto, and various forms can be adopted based on the gist of the present disclosure.

The "framework component" of the connector housing 20 refers to a component having sufficient hardness and strength to maintain a shape of the connector housing 20 itself so as to hold a position of the terminal member 70 against an external force applied to the terminal member 70 when the terminal member 70 and a counterpart terminal (not illustrated) are fitted together, for example. In other words, the framework component refers to a component made of a material that is not softened or fragile to such an extent that it is difficult to maintain its shape due to an increase in an operating temperature of the terminal member 70.

Hereinafter, each component constituting the connector housing 20 will be described in order.

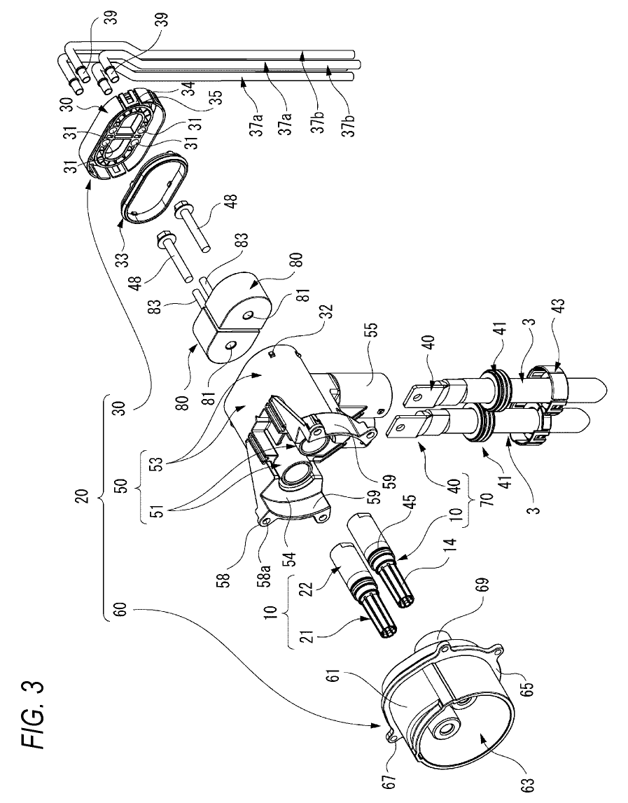

The holder 50 functions to hold the pair of terminal members 70 in a state of being spaced apart from each other in the left-right direction and insulated from each other. As illustrated in FIGS. 2 and 3, the holder 50 is integrally formed with a pair of terminal holding portions 51 arranged in the left-right direction, a pair of accommodating recesses 53 formed in a rear portion opposite to the terminal holding portions 51, and a pair of electric wire introduction portions 55 arranged in the left-right direction.

As illustrated in FIG. 3, each of the terminal holding portions 51 of the holder 50 has a cylindrical shape extending in the front-rear direction. Power terminals 10 of the pair of terminal members 70 are respectively inserted into internal spaces of the pair of terminal holding portions 51 from the front side.

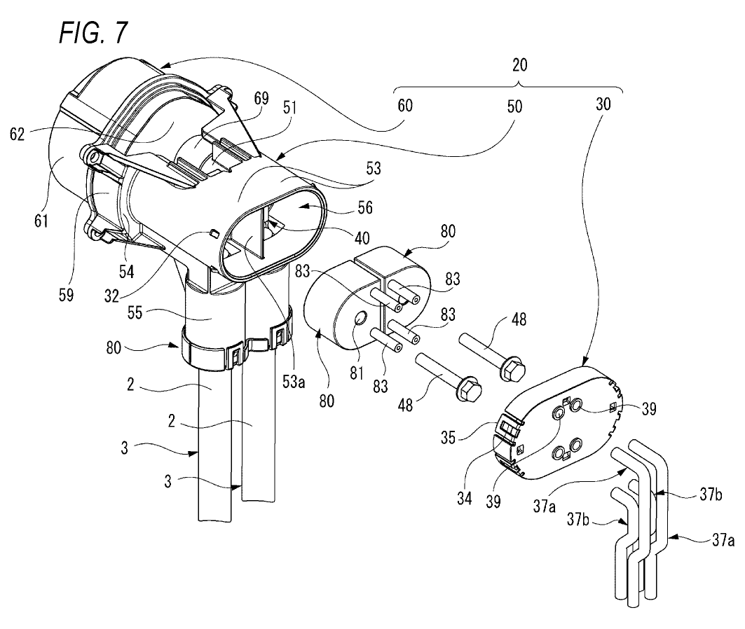

The accommodating recess 53 is formed in a recess shape in which a rear portion opposite to the terminal holding portion 51 is opened by an opening portion 56 having an oval cross section. The opening portion 56 of the holder 50 partitioned by a partition wall 53a (see FIG. 7) extending rearward from the terminal holding portion 51 is sealed by the cover 30 to be described later, thereby constituting accommodating spaces for respectively accommodating the refrigerant accommodating bodies 80 in which a refrigerant 100 is liquid-sealed. The accommodating recess 53 communicates with corresponding one of the internal spaces of the terminal holding portions 51.

The electric wire introduction portions 55 extend downward in a direction that intersects with the fitting direction in which the holder 50 is fitted to a counterpart connector. Electric wire through holes 57 communicating with the accommodating recesses 53 are respectively formed in the electric wire introduction portions 55. LA terminals 40 of the pair of terminal members 70 are respectively inserted into the electric wire through holes 57 from below.

As illustrated in FIG. 3, a pair of extending portions 54 respectively extending outward in the left-right direction from both side portions in the left-right direction of a front end portion of the holder 50 and a pair of side wall portions 59 respectively extending forward from extending end portions of the extending portions 54 are integrally provided at the front end portion. The pair of side wall portions 59 have a shape corresponding to a part in a peripheral direction of an outer peripheral shape (cylindrical shape) of a tubular portion 61 of the housing body 60 to be described later as viewed in the front-rear direction, and are mountable to the tubular portion 61 so as to cover an outer peripheral surface of a rear end portion of the tubular portion 61.

As illustrated in FIG. 3, screw insertion portions 58 are provided at a plurality of positions (four positions in the present embodiment) on outer peripheral surfaces (outer side faces in the left-right direction) of the pair of side wall portions 59. Screw through holes 58a penetrating in the front-rear direction are respectively formed in the screw insertion portions 58. Screws (not illustrated) for assembling the housing body 60 are respectively inserted into the screw through holes 58a.

Next, the housing body 60 will be described.

As illustrated in FIGS. 1 to 3, the housing body 60 is assembled to the holder 50 from the front side, and functions to form the recessed fitting portion 63 of the charging inlet 1. The housing body 60 is a resin molded product and integrally includes the tubular portion 61 extending in the front-rear direction and a rear wall portion 62 closing a rear opening of the tubular portion 61. The tubular portion 61 and the rear wall portion 62 define the recessed fitting portion 63 that is opened forward and recessed rearward.

The rear wall portion 62 is provided with a pair of cylindrical female terminal accommodating portions 64 corresponding to terminal connection portions 21 of the pair of power terminals 10 so as to protrude forward. Each of the female terminal accommodating portions 64 is located in the recessed fitting portion 63 and has an internal space penetrating in the front-rear direction.

The rear wall portion 62 is provided with a pair of cylindrical holder fitting portions 69 corresponding to the pair of female terminal accommodating portions 64 so as to protrude rearward. The holder fitting portion 69 is externally fitted to a front end portion of the terminal holding portion 51 of the holder 50 when assembled to the holder 50 from the front side.

As illustrated in FIG. 3, an annular flange portion 65 protruding radially outward of the tubular portion 61 is provided on an outer peripheral surface of the tubular portion 61 at a position behind a center in the front-rear direction. Screw through holes 67 penetrating in the front-rear direction are formed in the flange portion 65 at a plurality of positions (four positions in the present embodiment) in the peripheral direction corresponding to the plurality of screw through holes 58a of the holder 50. Screws for assembling the housing body 60 are respectively inserted into the screw through holes 67.

Next, the cover 30 will be described.

The cover 30 is formed in an oval plate shape, and is assembled to the pair of accommodating recesses 53 of the holder 50 from a rear side via an annular seal member 33 (see FIG. 3). Accordingly, the openings of the pair of accommodating recesses 53 of the holder 50 respectively accommodating the refrigerant accommodating bodies 80 are sealed by the cover 30.

A plurality of locking pieces 35 respectively having locking holes 34 are formed in a peripheral edge of the cover 30. Locking claws 32 formed on the holder 50 respectively enter the locking holes 34 of the locking pieces 35 by assembling the cover 30 to the holder 50. Accordingly, the locking pieces 35 are respectively locked by the locking claws 32, and the cover 30 is held in an assembled state with respect to the holder 50.

Ends of a pair of connection pipes 83 of each of the refrigerant accommodating bodies 80 respectively accommodated in the pair of accommodating recesses 53 respectively pass through, via rubber plugs 39, two pairs of openings 31 formed in the cover 30.

Next, the refrigerant accommodating bodies 80 according to the first embodiment will be described.

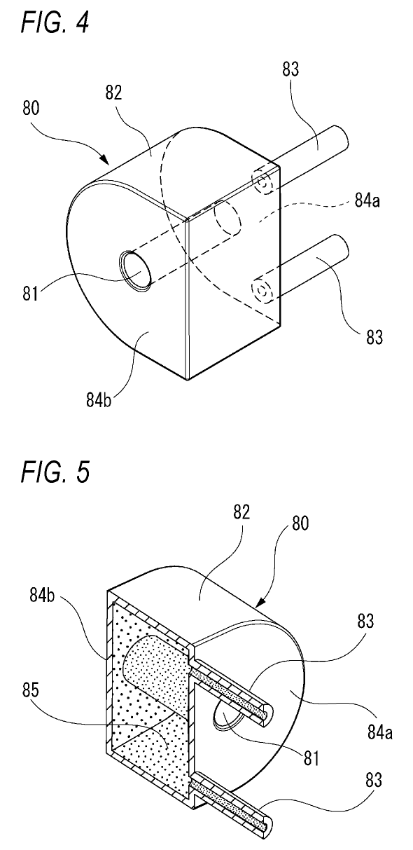

FIG. 4 is a perspective view of the refrigerant accommodating body 80, and FIG. 5 is a partially cutaway perspective view of the refrigerant accommodating body 80 as viewed from the rear.

In the present embodiment, the pair of refrigerant accommodating bodies 80 have the same shape. As illustrated in FIG. 4, each of the refrigerant accommodating bodies 80 includes a tubular case body portion 82, a pair of end portions 84a and 84b, and a cylindrical bolt insertion portion 81. The case body portion 82 has a substantially semicircular cross section and is formed such that an outer peripheral surface is in contact with an inner peripheral surface of the accommodating recess 53. The pair of end portions 84a and 84b close openings in both ends of the case body portion 82. The bolt insertion portion 81 liquid-tightly connects openings formed in the pair of end portions 84a and 84b.

As will be described later, a bolt 48 that fastens the LA terminal 40 to a rear end portion of the power terminal 10 is inserted into the bolt insertion portion 81 from one (right in FIG. 4) end portion 84a side, and the other (left in FIG. 4) end portion 84b of the refrigerant accommodating body 80 is integrally fixed in contact with the terminal member 70.

At the one end portion 84a, the pair of connection pipes 83 communicating with an internal space of the refrigerant accommodating body 80 are provided side by side in the upper-lower direction in the drawing. The pair of connection pipes 83 are respectively connected to a refrigerant outward path 37a and a refrigerant return path 37b as refrigerant paths communicating with a cooling device (not illustrated) that cools the refrigerant 100.

For example, of the pair of connection pipes 83, the connection pipe 83 disposed on a lower side is connected to the refrigerant outward path 37a, and the connection pipe 83 disposed on an upper side is connected to the refrigerant return path 37b. Therefore, the refrigerant 100 filled in the refrigerant accommodating body 80 can circulate between the refrigerant accommodating body 80 and the cooling device through the refrigerant outward path 37a and the refrigerant return path 37b.

That is, the refrigerant 100 cooled by the cooling device is supplied to the refrigerant accommodating body 80 accommodated in the accommodating recess 53 through the refrigerant outward path 37a, and is discharged from the refrigerant accommodating body 80 to the cooling device through the refrigerant return path 37b.

Therefore, the refrigerant 100 in the refrigerant accommodating body 80 always circulates through the refrigerant outward path 37a and the refrigerant return path 37b, so that a temperature difference from a heat generating portion is generated, heat is efficiently transferred and discharged, and temperature rise can be restrained.

The refrigerant outward path 37a and the refrigerant return path 37b are formed of an insulating resin pipe in order to be prevented from being short-circuited due to the connection pipe 83. Insulation can also be performed not by the refrigerant path itself using the resin pipes, but by a pipe joint provided in an intermediate portion of the refrigerant path.

As the cooling device, a cooling device for an in-vehicle battery mounted on a vehicle, a cooling device provided in a charger outside the vehicle, or the like can be used.

As illustrated in FIG. 5, in the refrigerant accommodating body 80 made of metal according to the first embodiment, an insulating layer 85 is provided on an entire inner surface in contact with the refrigerant 100 in order to be prevented from being short-circuited due to the refrigerant 100. The insulating layer 85 is formed by, for example, insulating treatment such as insulating coating (epoxy/vinyl chloride-based paint, polyurethane-based paint, or acrylic-based paint), an insulating sheet (resin sheet such as polyethylene terephthalate), a TIM (heat conductive and heat dissipation material: silicone/insulating material), or alumite treatment.

Therefore, as the refrigerant 100, water, coolant (LLC), oil, or the like, which is relatively inexpensive compared to insulating oil, can be used.

The refrigerant accommodating body 80 has a structure in which a part of the case body portion 82, the end portions 84a and 84b, the bolt insertion portion 81, and the connection pipes 83 is divided and configured as separate components, and the separate components can be combined in a water-stopped state by welding or an adhesive.

The material of the refrigerant accommodating body 80 is not limited to a metal material such as a copper alloy and an aluminum alloy having conductivity and good thermal conductivity, and a resin material can be used in some portions. In this case, the metal portion and the resin portion can be joined by vibration welding, ultrasonic welding, laser joining, an adhesive, or the like, or can be combined by insert molding.

Next, the terminal members 70 according to the first embodiment will be described.

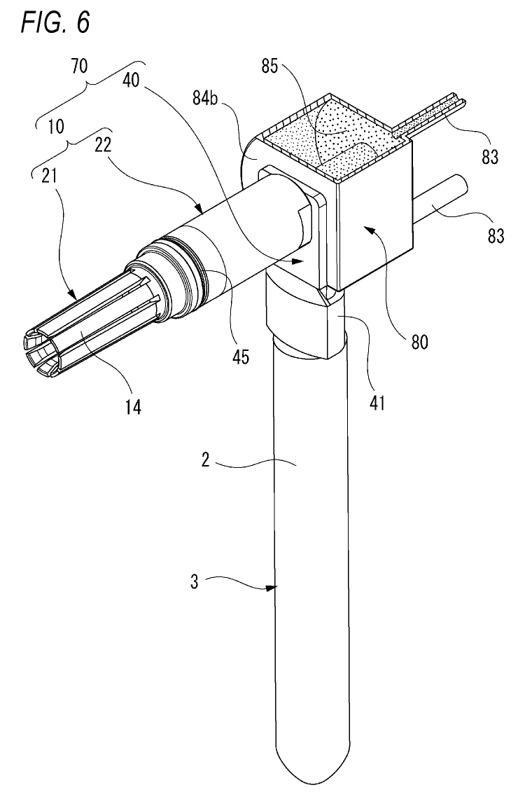

FIG. 6 is a partially cutaway perspective view illustrating a state in which the refrigerant accommodating body 80 is fixed to the terminal member 70.

In the present embodiment, the pair of terminal members 70 have the same shape. Each terminal member 70 is integrally configured by the power terminal 10 fitted to the counterpart terminal, the LA terminal 40 crimped to the core wire 4 of the electric wire 3, and the bolt 48 fastening the LA terminal 40 to the rear end portion of the power terminal 10 after being inserted into the bolt insertion portion 81 of the refrigerant accommodating body 80.

The power terminal 10 is made of metal, and as illustrated in FIGS. 3 and 6, includes the terminal connection portion 21 electrically connected to a counterpart terminal (male terminal) on a front end side and a holding portion 22 held by the holder 50 of the connector housing 20 on a rear end side.

The terminal connection portion 21 is a female terminal portion having a plurality of elastic contact pieces 14. The plurality of elastic contact pieces 14 have a substantially cylindrical shape, and the counterpart terminal (male terminal) is inserted into an interior thereof. The terminal connection portion 21 according to the first embodiment is not limited to the female terminal portion, and may be configured as a male terminal portion.

The holding portion 22 is formed in a short solid columnar shape, and an O-ring 45 is mounted in an annular groove formed on an outer peripheral surface of the holding portion 22. A screw hole 23 into which the bolt 48 is screwed is bored in a rear end surface of the holding portion 22.

Next, an assembling procedure of the charging inlet 1 according to the first embodiment will be described. FIG. 7 is a perspective view of the connector housing 20 in which the refrigerant accommodating body 80 is accommodated, as viewed from the rear side.

First, as illustrated in FIG. 2, the power terminal 10 is inserted into the internal space of the terminal holding portion 51 of the connector housing 20 from the front side. The O-ring 45 mounted to the power terminal 10 is pressed into contact with an inner wall surface of the terminal holding portion 51, so that a space between the terminal holding portion 51 and the power terminal 10 is sealed.

Then, the electric wire 3 whose end is connected to the LA terminal 40 is passed through the electric wire introduction portion 55 of the holder 50, and the LA terminal 40 is arranged at the rear end portion of the power terminal 10. After the refrigerant accommodating body 80 is inserted into the accommodating recess 53, the LA terminal 40 is fastened to the power terminal 10 by the bolt 48 inserted into the bolt insertion portion 81 from the rear side.

Therefore, the terminal member 70 whose power terminal 10 is held by the terminal holding portion 51 is accommodated in the connector housing 20. As illustrated in FIGS. 2 and 6, the refrigerant accommodating body 80 is accommodated in the connector housing 20 in a state in which the other end portion 84b is in contact with the terminal member 70.

That is, the power terminal 10, the LA terminal 40, and the refrigerant accommodating body 80 that are in direct contact with each other are fastened together by the bolt 48, thereby stably securing a surface pressure between the components, reducing an interface resistance, and improving heat conductivity from the terminal member 70 that is a heating element to the refrigerant accommodating body 80.

The rubber plug 41 is mounted on the electric wire 3, and a space between the electric wire end of the electric wire 3 and the electric wire through hole 57 of the electric wire introduction portion 55 is sealed by the rubber plug 41. The rubber plug 41 is retained by a rear holder 43 mounted on a lower end of the electric wire introduction portion 55.

Next, as illustrated in FIG. 7, the cover 30 is assembled to the connector housing 20, and the locking claws 32 of the connector housing 20 are locked to the locking pieces 35 of the cover 30. Then, in the connector housing 20, the opening portion 56 of the holder 50, which is also an assembly work hole for the terminal members 70 and the refrigerant accommodating bodies 80, is covered by the cover 30 by assembling the cover 30.

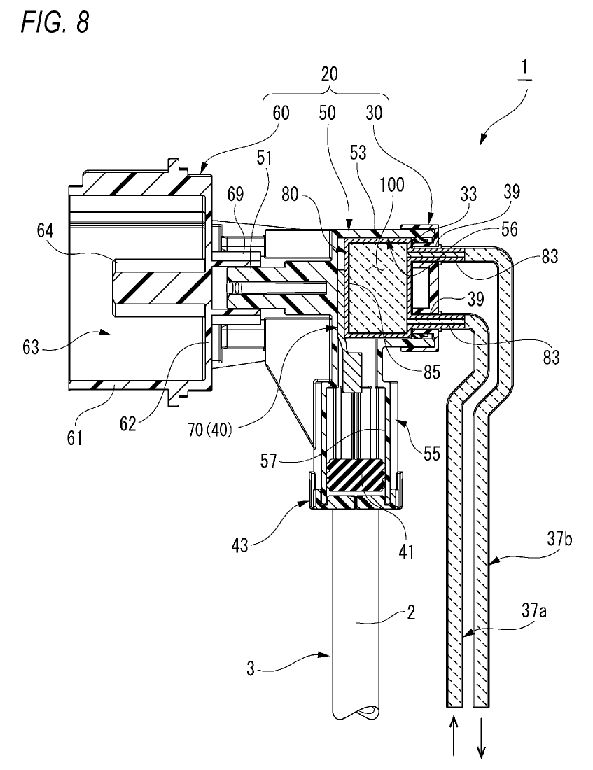

At this time, as illustrated in FIGS. 2 and 8, the opening portion 56 of the holder 50 is sealed by the seal member 33 of the cover 30. The space between the terminal holding portion 51 with which the accommodating recess 53 communicates and the power terminal 10 is sealed by the O-ring 45, and the space between the electric wire introduction portion 55 with which the accommodating recess 53 communicates and the electric wire 3 is sealed by the rubber plug 41.

Next, an operation of the charging inlet 1 according to the first embodiment described above will be described.

FIG. 8 is a sectional view taken along a line VIII-VIII of FIG. 1.

When the charging gun is fitted to the charging inlet 1 illustrated in FIG. 1, a charging current is supplied from a charger outside the vehicle to the battery mounted on the vehicle through the charging gun and the charging inlet 1. In particular, when a large charging current is supplied from the charger outside the vehicle to the battery in order to shorten a charging time, heat is likely to be generated at a contact portion between the counterpart terminal of the charging gun and the power terminal 10 of the terminal member 70 of the charging inlet 1.

At this time, in the charging inlet 1 according to the first embodiment, as illustrated in FIG. 8, the refrigerant accommodating body 80 is accommodated in the accommodating recess 53 in a state of being in contact with the terminal member 70 held by the terminal holding portion 51 of the connector housing 20, and the refrigerant 100 circulates in the refrigerant accommodating body 80. That is, the refrigerant accommodating body 80 in which the refrigerant 100 circulates and is cooled is accommodated in the accommodating recess 53 and is configured to be able to be in direct contact with the heated terminal member 70.

Therefore, according to the charging inlet 1 according to the first embodiment, since the heated terminal member 70 can be brought into direct contact with the refrigerant accommodating body 80 cooled by the refrigerant 100 circulating from the outside, a thermal resistance is reduced, and high cooling performance can be obtained. The refrigerant 100 in the refrigerant accommodating body 80 always circulates, so that a temperature difference from a heat generating portion is generated, heat is efficiently transferred and discharged, and a temperature rise can be restrained.

Since the accommodating recess 53 accommodating the refrigerant accommodating body 80 can be easily formed in the holder 50 of the connector housing 20 and it is not necessary to form a refrigerant flow path in the terminal member 70, an increase in manufacturing cost of the charging inlet 1 can be restrained.

In the charging inlet 1 according to the first embodiment, the refrigerant accommodating body 80 includes the bolt insertion portion 81, and the terminal member 70 includes the power terminal 10 fitted to the counterpart terminal and the LA terminal 40 fastened to the power terminal 10 by the bolt 48 inserted into the bolt insertion portion 81.

Therefore, when the charging inlet 1 is assembled, by inserting the power terminal 10 into the terminal holding portion 51, passing the electric wire 3 whose electric wire end is connected to the LA terminal 40 through the electric wire introduction portion 55 of the holder 50, and then fastening the LA terminal 40 to the rear end portion of the power terminal 10 by the bolt 48 inserted into the bolt insertion portion 81, the refrigerant accommodating body 80 can be easily accommodated in the connector housing 20 in the state of being in direct contact with the terminal member 70. The power terminal 10, the LA terminal 40, and the refrigerant accommodating body 80 that are in direct contact with each other are fastened together by the bolt 48, thereby stably securing a surface pressure between the components, reducing an interface resistance, and improving heat conductivity from the terminal member 70 that is a heating element to the refrigerant accommodating body 80.

In the charging inlet 1 according to the first embodiment, in the refrigerant accommodating body 80 which is made of metal and in which the refrigerant 100 having conductivity circulates, the insulating layer 85 is provided on the entire inner surface in contact with the refrigerant 100.

Therefore, the refrigerant accommodating body 80 that is in direct contact with the terminal member 70 in order to reduce the thermal resistance is prevented from being short-circuited due to the refrigerant 100 having conductivity.

### Modification

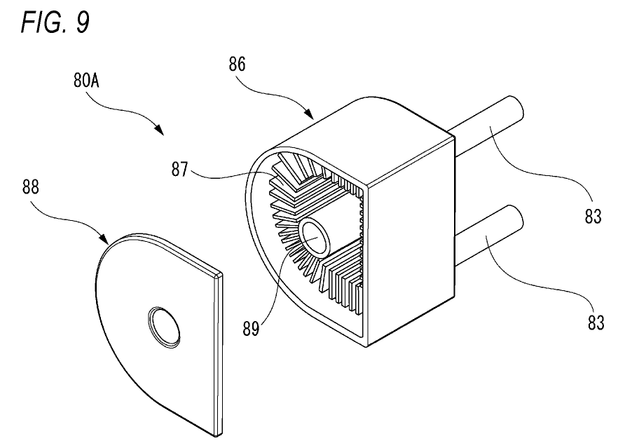

FIG. 9 is an exploded perspective view of a refrigerant accommodating body 80A according to a modification.

As illustrated in FIG. 9, the refrigerant accommodating body 80A according to the modification includes a bottomed tubular case body portion 86, a lid body 88, and a cylindrical bolt insertion portion 89. The case body portion 86 has a substantially semicircular cross section and is formed such that an outer peripheral surface is in contact with the inner peripheral surface of the accommodating recess 53. The lid body 88 closes an opening end of the case body portion 86. The bolt insertion portion 89 connects an opening formed in a bottom portion of the case body portion 86 and an opening formed in the lid body 88. At the bottom portion of the case body portion 86, the pair of connection pipes 83 communicating with an internal space of the refrigerant accommodating body 80A are provided side by side in the upper-lower direction in the drawing.

A plurality of heat dissipation protrusions 87 increasing a surface area of an inner surface and improving heat dissipation property are provided inside the case body portion 86. Each of the heat dissipation protrusions 87 is a rectangular flat plate-shaped fin extending from the bottom portion toward the opening end along an inner peripheral surface of the case body portion 86. The insulating layer 85 (not illustrated) is provided on an entire inner surfaces of the case body portion 86 and the lid body 88.

It goes without saying that a shape of the heat dissipation protrusion according to the present disclosure can adopt various forms based on the gist of the present disclosure.

The refrigerant 100 cooled by the cooling device is supplied to the refrigerant accommodating body 80A accommodated in the accommodating recess 53 through the refrigerant outward path 37a, and is discharged from the refrigerant accommodating body 80A to the cooling device through the refrigerant return path 37b.

At this time, in the refrigerant accommodating body 80A in which the plurality of heat dissipation protrusions 87 increasing the surface area and improving the heat dissipation property are provided on the inner surface of the case body portion 86, a thermal resistance between the refrigerant 100 and the case body portion 86 can be reduced. Therefore, according to the charging inlet 1 including the refrigerant accommodating body 80A, heat is efficiently transferred and discharged, and a temperature rise can be restrained.

The case body portion 86 is integrally molded using an insulating resin, so that the plurality of heat dissipation protrusions 87 can be easily formed. The lid body 88 is formed of a conductive metal, a decrease in heat conductivity when the lid body 88 is in direct contact with the terminal member 70 is restrained. The case body portion 86 and the lid body 88 are joined by vibration welding or the like.

### Second Embodiment

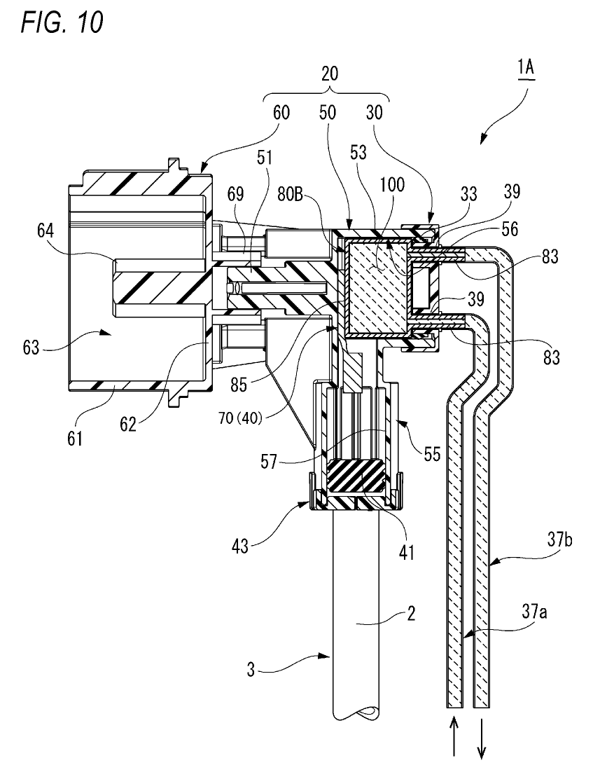

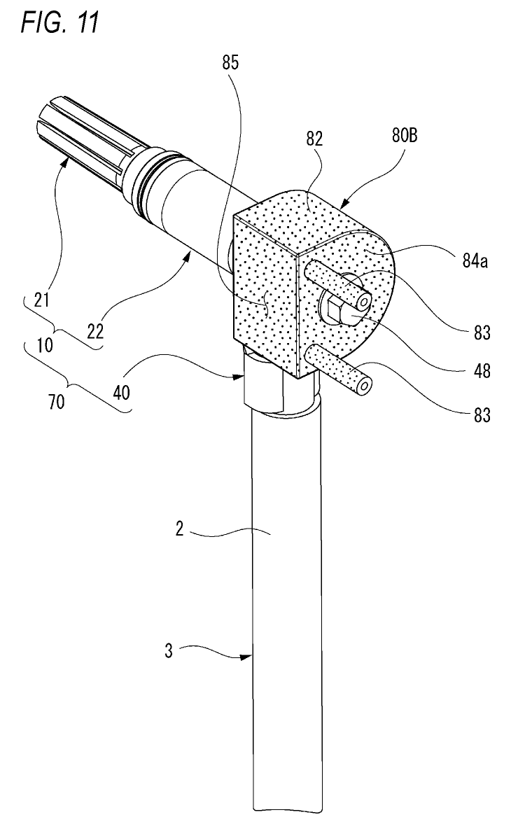

FIG. 10 is a longitudinal sectional view of a charging inlet 1A according to a second embodiment of the present disclosure. FIG. 11 is a perspective view illustrating a state in which a refrigerant accommodating body 80B illustrated in FIG. 10 is fixed to the terminal member 70, as viewed from the rear. The charging inlet 1A according to the second embodiment has a configuration in which the refrigerant accommodating bodies 80 in the charging inlet 1 according to the first embodiment are replaced with the refrigerant accommodating bodies 80B, and thus the same components are denoted by the same reference numerals, and detailed description thereof will be omitted.

As illustrated in FIG. 10, the charging inlet 1A according to the second embodiment includes the pair of terminal members 70 to each of which one end portion of corresponding one of the pair of electric wires 3 is electrically connected, the pair of refrigerant accommodating bodies 80B that are respectively fixed in contact with the terminal members 70, and the connector housing 20 that accommodates the pair of terminal members 70 and the pair of refrigerant accommodating bodies 80B.

As illustrated in FIG. 11, each of the refrigerant accommodating bodies 80B includes the tubular case body portion 82, the pair of end portions 84a and 84b, and the cylindrical bolt insertion portion 81 (not illustrated). The case body portion 82 has the substantially semicircular cross section and is formed such that the outer peripheral surface is in contact with the inner peripheral surface of the accommodating recess 53. The pair of end portions 84a and 84b close the openings in both ends of the case body portion 82. The bolt insertion portion 81 liquid-tightly connects the openings formed in the pair of end portions 84a and 84b.

In the refrigerant accommodating body 80B made of metal according to the second embodiment, the insulating layer 85 is provided on an entire outer surface in order to be prevented from being short-circuited due to the refrigerant 100.

The insulating layer 85 according to the second embodiment is not necessarily provided on the entire outer surface of the refrigerant accommodating body 80B, and may be provided on an outer surface including at least a fastening surface of the refrigerant accommodating body 80B. Here, the fastening surface includes a part of one end portion 84a with which a seat surface of the bolt 48 is in contact, a part of the other end portion 84b with which the LA terminal 40 of the terminal member 70 is in contact, and an inner peripheral surface of the bolt insertion portion 81 when the LA terminal 40 is fastened to the power terminal 10 by the bolt 48 inserted into the bolt insertion portion 81 of the refrigerant accommodating body 80B.

Therefore, according to the charging inlet 1A according to the second embodiment, similarly to the charging inlet 1 according to the first embodiment, since the heated terminal member 70 can be brought into direct contact with the refrigerant accommodating body 80B cooled by the refrigerant 100 circulating from the outside, a thermal resistance is reduced, and high cooling performance can be obtained. The refrigerant 100 in the refrigerant accommodating body 80B always circulates, so that a temperature difference from a heat generating portion is generated, heat is efficiently transferred and discharged, and a temperature rise can be restrained.

When the charging inlet 1A is assembled, by inserting the power terminal 10 into the terminal holding portion 51, passing the electric wire 3 whose electric wire end is connected to the LA terminal 40 through the electric wire introduction portion 55 of the holder 50, and then fastening the LA terminal 40 to the rear end portion of the power terminal 10 by the bolt 48 inserted into the bolt insertion portion 81, the refrigerant accommodating body 80B can be easily accommodated in the connector housing 20 in a state of being in direct contact with the terminal member 70. The power terminal 10, the LA terminal 40, and the refrigerant accommodating body 80B that are in direct contact with each other are fastened together by the bolt 48, thereby stably securing a surface pressure between the components, reducing an interface resistance, and improving heat conductivity from the terminal member 70 that is a heating element to the refrigerant accommodating body 80B.

In the charging inlet 1A according to the second embodiment, in the refrigerant accommodating body 80B which is made of metal and in which the refrigerant 100 having conductivity circulates, the insulating layer 85 is provided on the entire outer surface.

Therefore, the refrigerant accommodating body 80B that is in direct contact with the terminal member 70 in order to reduce the thermal resistance is prevented from being short-circuited due to the refrigerant 100.

Similarly to the refrigerant accommodating body 80A according to the modification described above, the plurality of heat dissipation protrusions 87 increasing a surface area of an inner surface and improving heat dissipation property can be provided inside the refrigerant accommodating body 80B.

Therefore, according to the charging inlet 1A according to the second embodiment, heat is efficiently transferred and discharged, and a temperature rise can be restrained. It is possible to provide the charging inlet 1A that can restrain temperature rise of the terminal member 70 during energization and is easily manufactured.

### Reference Example

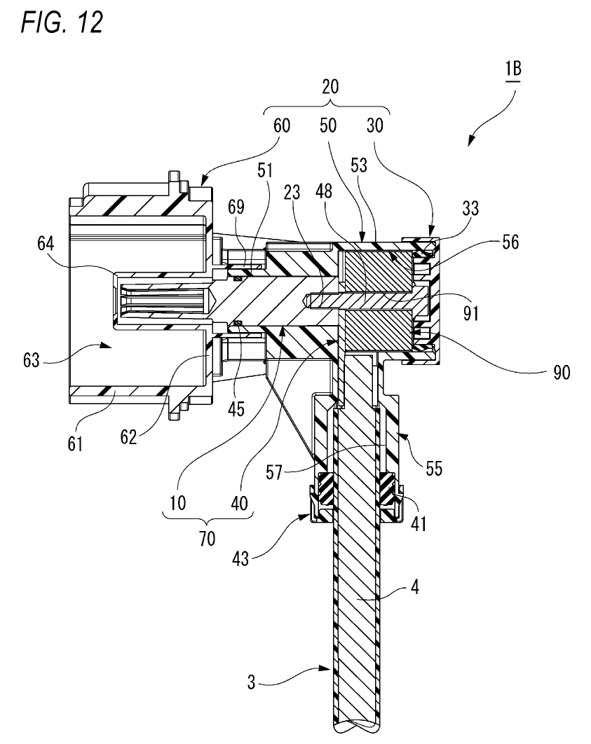

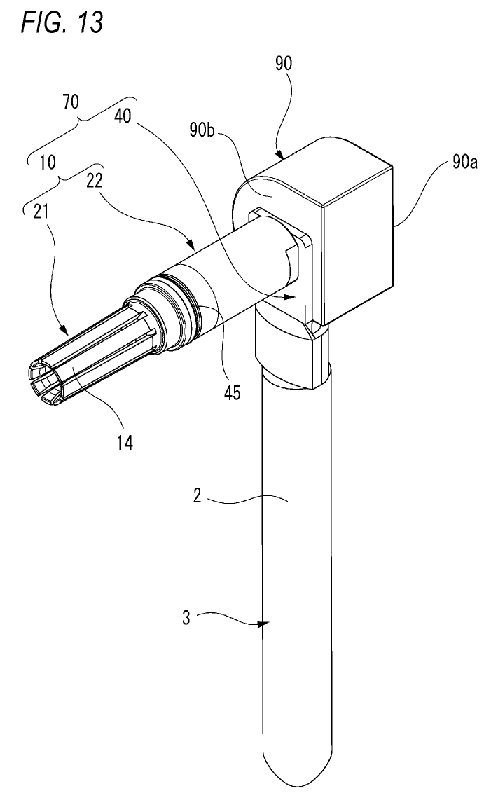

FIG. 12 is a longitudinal sectional view of a charging inlet 1B according to a reference example. FIG. 13 is a perspective view illustrating a state in which a heat storage member 90 illustrated in FIG. 12 is fixed to the terminal member 70. The charging inlet 1B according to the reference example has a configuration in which the heat storage members 90 are used instead of the refrigerant accommodating bodies 80 in which the refrigerant 100 circulates, and thus the same components as those of the charging inlet 1 are denoted by the same reference numerals, and detailed description thereof will be omitted.

As illustrated in FIG. 12, the charging inlet 1B according to the reference example includes the pair of terminal members 70 to each of which one end portion of corresponding one of the pair of electric wires 3 is electrically connected, the pair of heat storage members 90 that are respectively fixed in contact with the terminal members 70, and the connector housing 20 that accommodates the pair of terminal members 70 and the pair of heat storage members 90.

In the present embodiment, the pair of heat storage members 90 have the same shape. Each of the heat storage members 90 is formed in a columnar shape having a substantially semicircular cross section such that an outer peripheral surface is in contact with the inner peripheral surface of the accommodating recess 53 (see FIG. 13). A bolt insertion portion 91 which has a circular cross section and into which the bolt 48 is inserted is formed between a pair of end portions 90a and 90b.

As illustrated in FIG. 13, the bolt 48 that fastens the LA terminal 40 to the rear end portion of the power terminal 10 is inserted into the bolt insertion portion 91 from one end portion 90a side, and the other end portion 90b of the heat storage member 90 is integrally fixed in contact with the terminal member 70.

Therefore, according to the charging inlet 1B according to the reference example, since the heated terminal member 70 can be brought into direct contact with the heat storage member 90, a thermal resistance is reduced, and high cooling performance can be obtained.

Since the accommodating recess 53 accommodating the heat storage member 90 can be easily formed in the holder 50 of the connector housing 20 and it is not necessary to form a refrigerant flow path in the terminal member 70, an increase in manufacturing cost of the charging inlet 1B can be restrained.

In the charging inlet 1B according to the reference example, by fastening the LA terminal 40 to the rear end portion of the power terminal 10 by the bolt 48 inserted into the bolt insertion portion 91, the heat storage member 90 can be easily accommodated in the connector housing 20 in a state of being in direct contact with the terminal member 70. The power terminal 10, the LA terminal 40, and the heat storage member 90 that are in direct contact with each other are fastened together by the bolt 48, thereby stably securing a surface pressure between the components, reducing an interface resistance, and improving heat conductivity from the terminal member 70 that is a heating element to the heat storage member 90.

However, when a larger current flows, a temperature requirement cannot be satisfied only by heat storage of the heat storage member 90. In contrast, according to the charging inlet 1, 1A according to the first embodiment and the second embodiment described above, since the heated terminal member 70 can be brought into direct contact with the refrigerant accommodating body 80, 80A, 80B cooled by the refrigerant 100 circulating from the outside, the thermal resistance is reduced, and the high cooling performance can be obtained. The refrigerant 100 in the refrigerant accommodating body 80, 80A, 80B always circulates, so that a temperature difference from a heat generating portion is generated, heat is efficiently transferred and discharged, and a temperature rise can be restrained.

The present disclosure is not limited to the embodiment described above, and can be appropriately modified, improved, and the like. In addition, materials, shapes, dimensions, numbers, arrangement positions, and the like of the components in the embodiments described above are freely selected and are not limited as long as the present disclosure can be implemented.

For example, in the charging inlet 1, 1A described above, the refrigerant 100 such as water, coolant (LLC), or oil which is relatively inexpensive is used. In contrast, when insulating oil, insulating coolant, or the like is used as the refrigerant circulating in the refrigerant accommodating body, it is not necessary to provide the insulating layer 85 in the refrigerant accommodating body as in the refrigerant accommodating body 80, 80A, 80B described above.

In the charging inlet 1, 1A described above, the terminal member 70 is integrally formed by fastening the power terminal 10 and the LA terminal 40 by the bolt 48, but the terminal member according to the present disclosure is not limited thereto, and it goes without saying that various forms can be adopted based on the gist of the present disclosure.

Here, features of the embodiments of the connector according to the present disclosure described above are briefly summarized and listed in the following [1] to [5]. [1] A connector (charging inlet 1, 1A) includes:

a terminal member (70);

a connector housing (20) configured to hold the terminal member (70);

a refrigerant accommodating body (80, 80A, 80B) configured to be accommodated in the connector housing (20) in a state of being in contact with the terminal member (70); and

a refrigerant (100) configured to circulate in the refrigerant accommodating body (80, 80A, 80B) from outside.

According to the connector (charging inlet 1, 1A) having the configuration in above [1], the refrigerant accommodating body (80, 80A, 80B) in which the refrigerant (100) circulates and is cooled can be in direct contact with the heated terminal member (70).

Therefore, since the heated terminal member (70) can be brought into direct contact with the refrigerant accommodating body (80, 80A, 80B) cooled by the refrigerant 100 circulating from the outside, a thermal resistance is reduced, and high cooling performance can be obtained. The refrigerant (100) in the refrigerant accommodating body (80, 80A, 80B) always circulates, so that a temperature difference from a heat generating portion is generated, heat is efficiently transferred and discharged, and a temperature rise can be restrained.

Since the accommodating recess (53) accommodating the refrigerant accommodating body (80, 80A, 80B) can be easily formed in the connector housing (20) and it is not necessary to form a refrigerant flow path in the terminal member (70), an increase in manufacturing cost of the connector (charging inlet 1, 1A) can be restrained.

[2] The connector (charging inlet 1) according to above [1], in which

in the refrigerant accommodating body (80, 80A) which is made of metal and in which the refrigerant (100) having conductivity circulates, an insulating layer (85) is provided on an entire inner surface in contact with the refrigerant (100).

According to the connector (charging inlet 1) having the configuration in above [2], the refrigerant accommodating body (80, 80A) that is in direct contact with the terminal member (70) in order to reduce the thermal resistance is prevented from being short-circuited due to the refrigerant (100) having conductivity.

[3] The connector (charging inlet 1) according to above [2], in which

the refrigerant accommodating body (80, 80A) includes a bolt insertion portion (81) into which a bolt (48) is inserted, and

the terminal member (70) includes a power terminal (10) configured to be fitted to a counterpart terminal and an LA terminal (40) configured to be fastened to the power terminal (10) by the bolt (48) inserted into the bolt insertion portion (81).

According to the connector (charging inlet 1) having the configuration in above [3], when the connector (charging inlet 1) is assembled, by inserting the power terminal (10) into the terminal holding portion, passing the electric wire (3) whose electric wire end is connected to the LA terminal (40) through the electric wire introduction portion of the connector housing (20), and then fastening the LA terminal (40) to a rear end portion of the power terminal (10) by the bolt (48) after the bolt (48) is inserted into the bolt insertion portion (81) of the refrigerant accommodating body (80, 80A), the terminal member (70) can be easily accommodated in the connector housing (20).

[4] The connector (charging inlet 1A) according to above [1], in which

the refrigerant accommodating body (80B) made of metal includes a bolt insertion portion (81) into which a bolt (48) is inserted,

the terminal member (70) includes a power terminal (10) configured to be fitted to a counterpart terminal and an LA terminal (40) configured to be fastened to the power terminal (10) by the bolt (48) inserted into the bolt insertion portion (81), and

an insulating layer (85) is provided on an outer surface including at least a fastening surface of the refrigerant accommodating body (80B) in which the refrigerant (100) having conductivity circulates.

According to the connector (charging inlet 1A) having the configuration in above [4], since the insulating layer (85) is provided on the outer surface including at least the fastening surface of the refrigerant accommodating body (80B) which is made of metal and in which the refrigerant (100) having conductivity circulates, the refrigerant accommodating body (80B) that is in direct contact with the terminal member (70) in order to reduce the thermal resistance is prevented from being short-circuited due to the refrigerant (100). [5] The connector (charging inlet 1) according to any one of above [1] to [4], in which

a heat dissipation protrusion (87) increasing a surface area of an inner surface and improving heat dissipation property is provided inside the refrigerant accommodating body (80A).

According to the connector (charging inlet 1) having the configuration in above [5], a thermal resistance between the refrigerant (100) and the refrigerant accommodating body (80A) can be reduced. Therefore, according to the charging inlet (1) including the refrigerant accommodating body (80A), heat is efficiently transferred and discharged, and a temperature rise can be restrained.

1. A connector comprising:
a terminal member;
a connector housing configured to hold the terminal member;
a refrigerant accommodating body configured to be accommodated in the connector housing in a state of being in contact with the terminal member; and
a refrigerant configured to circulate in the refrigerant accommodating body from outside.

2. The connector according to claim 1, wherein
in the refrigerant accommodating body which is made of metal and in which the refrigerant having conductivity circulates, an insulating layer is provided on an entire inner surface in contact with the refrigerant.

3. The connector according to claim 2, wherein
the refrigerant accommodating body includes a bolt insertion portion into which a bolt is inserted, and
the terminal member includes a power terminal configured to be fitted to a counterpart terminal and an LA terminal configured to be fastened to the power terminal by the bolt inserted into the bolt insertion portion.

4. The connector according to claim 1, wherein
the refrigerant accommodating body made of metal includes a bolt insertion portion into which a bolt is inserted,
the terminal member includes a power terminal configured to be fitted to a counterpart terminal and an LA terminal configured to be fastened to the power terminal by the bolt inserted into the bolt insertion portion, and
an insulating layer is provided on an outer surface including at least a fastening surface of the refrigerant accommodating body in which the refrigerant having conductivity circulates.

5. The connector according to claim 1, wherein
a heat dissipation protrusion increasing a surface area of an inner surface and improving heat dissipation property is provided inside the refrigerant accommodating body.
